(19) United States
(12) Patent Application Publication
(10) Pub. No.: US 2007/0057274 A1
(43) Pub. Date: Mar. 15, 2007

(54) White-light luminescent silicon-nitride component with silicon quantum dots and fabricating method thereof

(75) Inventors: Tsun-Neng Yang, Taoyuan (TW); Shan-Ming Lan, Taoyuan (TW)

Correspondence Address: TROXELL LAW OFFICE PLLC;SUITE 1404, 5205 LEESBURG PIKE, FALLS CHURCH, VA, 22041, US

(73) Assignee: Atomic Energy Council - Institute of Nuclear Energy Research

(21) Appl. No.: 11/221,851

(22) Filed: Sep. 9, 2005

(51) Int. Cl. H01L 33/00

(52) U.S. Cl. 257/100

(57) ABSTRACT

The present invention provides a luminescent component with silicon quantum dots and its fabricating method, where the luminescent component includes a light-emitting device of high luminescent efficiency, large-area luminescence, cheap raw material and low producing cost.

### FIELD OF THE INVENTION

The present invention relates to a luminescent component and a fabricating method thereof; more particularly, relates to obtaining a light-emitting device of silicon-nitride having silicon quantum dots with high luminescent efficiency, large-area luminescence, cheap raw material and low producing cost.

### DESCRIPTION OF THE RELATED ART

A white-light emitting diode of a prior art together with its fabricating method is disclosed in Taiwan. The white-light emitting diode comprises:

a first conductive electrode;

a substrate ohmically contacted with the first conductive electrode, which is made of gallium arsenide (GaAs), gallium phosphide (GaP) , silicon (Si) or silicon carbide (3 C-sic);

a first light-emitting part formed on the substrate, containing a first-type binding layer, an active layer and a second-type binding layer, where the first light-emitting part is made of a compound series of aluminum gallium indium phosphide (AlGaInP);

a buffer layer formed on the second-type binding layer of the first light-emitting part, which is made of B_{X}Ga₍₁₋ₓ₎P and In_{y}Ga_{(1-y)}N, 0≦x1 and 0≦y23 1;

a second light-emitting part formed on the first buffer layer, containing another first-type binding layer, an other active layer and another second-type binding layer, where the second light-emitting part is made of a compound series of aluminum gallium indium phosphide (AlGaInP);

and a second conductive electrode ohmically contacted with the second-type binding layer of the second light-emitting part.

When a potential difference is formed between the second conductive electrode and the first conductive electrode from outside, a current passes through the second light-emitting part, the buffer layer and the first light-emitting part. Hence, the active layer of the first light-emitting part emits a light having a wavelength within a first range; the active layer of the second light-emitting part emits a light having a wavelength within a second range; and, a white light is obtained by mixing the light having the first range of wavelength and the light having the second range of wavelength.

The fabricating method of the prior art comprises the following steps:

1. A substrate is selected, which is contacted with a first conductive electrode and is made of gallium arsenide, gallium phosphide, silicon or silicon carbide.

2. A first-type binding layer, an active layer and a second-type binding layer is formed on the substrate one by one to construct the first light-emitting part which is made of a compound series of aluminum gallium indium phosphide.

3. A buffer layer is formed on the second-type binding layer of the first light-emitting part, which is constructed of BₓGa₍₁₋ₓ₎P and In_{y}Ga_{(1-y)}N, 0≦x≦1 and 0≦y≦1.

4. Another first-type binding layer, another active layer and another second-type binding layer is formed on the buffer layer one by one to construct the second light-emitting part which is made of a compound series of aluminum gallium indium phosphide.

5. And, a second conductive electrode is formed on a surface of the second-type binding layer of the second light-emitting part.

Although the prior art can fabricate a white-light emitting diode, the light emitting diode obtaining white light by mixing two lights is expansive and so the total production cost is increased; and, regarding its physical characteristic, its luminescent efficiency is lower. In addition, its fabricating method is more complex and difficult when fabricating a light emitting diode having a large area. So, the prior art does not fulfill users' requests on actual use.

### SUMMARY OF THE INVENTION

Therefore, the main purpose of the present invention is to obtain a light-emitting device with high luminescent efficiency.

The secondary purpose of the present invention is to obtain a light-emitting device with large-area luminescence.

The third purpose of the present invention is to obtain a light-emitting device with cheap raw material and low producing cost.

To achieve the above purposes, the present invention is a white-light luminescent silicon-nitride component with silicon quantum dots and a fabricating method thereof, where a substrate is selected; on a surface of the substrate is applied with a precursor of dicholosilane (Si₂H₂Cl₂) together with nitrous oxide (N₂O), or Silane (SiH₄) together with ammonia (NH₃) to deposit a silicon nitride film layer with silicon quantum dots having a thickness between 1 μm and 10 μm and a light spectrum of wavelength between 400 nm and 700 nm ; on a surface of the silicon nitride film layer is correspondingly deposed with a light-emitting device having a wavelength smaller than 400 nm; and the light-emitting device emits a light source to the silicon nitride film layer to pump the silicon nitride film layer for generating a white light. Accordingly, a novel white-light luminescent silicon-nitride component with silicon quantum dots and a fabricating method thereof are obtained.

### BRIEF DESCRIPTION OF THE DRAWINGS

The present invention will be better understood from the following detailed descriptions of the preferred embodiments according to the present invention, taken in conjunction with the accompanying drawings, in which

FIG. 1 is a cross-sectional view of a first preferred embodiment according to the present invention;

FIG.2 is a cross-sectional view of a second preferred embodiment according to the present invention; and

FIG. 3 is a cross-sectional view of a third preferred embodiment according to the present invention.

### DESCRIPTION OF THE PREFERRED EMBODIMENTS

The following descriptions of the preferred embodiments are provided to understand the features and the structures of the present invention.

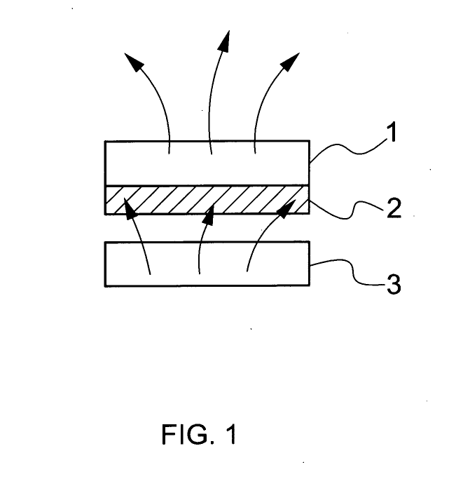

Please refer to FIG. 1, which is a cross-sectional view of a first preferred embodiment according to the present invention. As shown in the figure, the present invention is a white-light luminescent silicon-nitride component with silicon quantum dots and a fabricating method thereof. The white-light luminescent silicon-nitride component with silicon quantum dots comprises a substrate 1; a silicon nitride film layer 2 with si licon quantum dots deposed on the substrate 1; and a light-emitting device 3 corresponding to the silicon nitride film layer 2, where the light-emitting device 3 comprises high luminescent efficiency, large-area luminescence, cheap raw material and low producing cost.

Therein, the light-emitting device 3 is deposed on a surface of the silicon nitride film layer 2, emitting a light source to the silicon nitride film layer 2 to pump the silicon nitride film layer 2 for generating a required white light.

The fabricating method for the white-light luminescent silicon-nitride component comprises the following steps:

Step (A): A substrate 1 is selected. The substrate 1 can be a glass or a quartz with a thickness equal to or smaller than 1 mm (millimeter) in a flat shape. A precursor, which can be dichlorosilane (Si₂ H₂Cl₂) together with nitrous oxide ( N₂O) , or Silane (SiH₄) together with ammonia (NH₃), is applied on the substrate 1. By using an apparatus for AP-CVD (atmospheric pressure chemical vapor deposition) under a grown temperature between 800° C. (centigrade) to 1000° C. or by using an apparatus for PE-CVD (plasma-enhanced chemical vapor deposition) under a grown temperature between 300° C. to 500° C., a silicon nitride compound with a non-stoichiometric ratio is deposited on the substrate 1 having a thickness between 1 μm (micrometer) and 10 μm. After processing the substrate 1 with a proper therm o-treatment, silicon quantum dots each with a diameter smaller than 5 nm (nanometer) are evenly distributed on the substrate 1 to form a silicon nitride film layer 2 with silicon quantum dots having a light spectrum of wavelength between 400 nm to 700 nm. The silicon nitride film layer 2 can be a a white-light film, a fluorescence film or a ceramic insulator film.

Step (B): A light-emitting device 3 with a wavelength smaller than 400 nm is selected. The light-emitting device 3 is deposed correspondingly on a surface of the silicon nitride film layer 2. The light-emitting device 3 can be a UV-LED (Ultraviolet Light-Emitting Diode) or a device emitting a light source of the same kind, where the light source is emitted to the silicon nitride film layer 2 to pump the silicon nitride film layer 2 for generating a white light.

Thus, a white-light luminescent silicon-nitride component with silicon quantum dots and a fabricating method thereof are obtained.

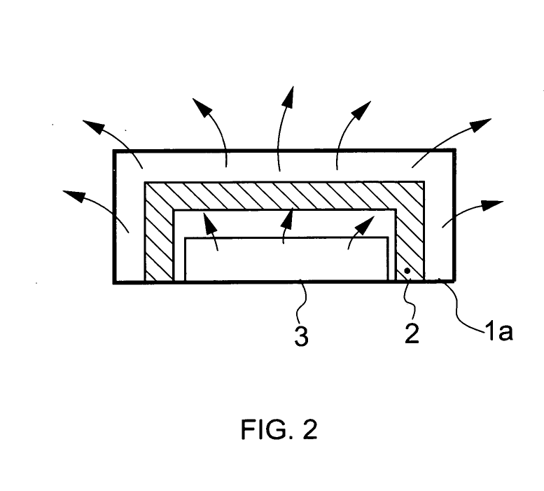

Please further refer to FIG. 2, which is a cross-sectional view of a second preferred embodiment according to the present invention. As shown in the figure, the substrate 1 can be of a flat shape as shown in FIG. 1; or, the substrate 1 a can be of a cap shape or any other shape according to the actual requirements, where a light source is emitted from the light-emitting device 3 to the silicon nitride film layer 2 to pump the silicon nitride film layer 2 for generating a white light.

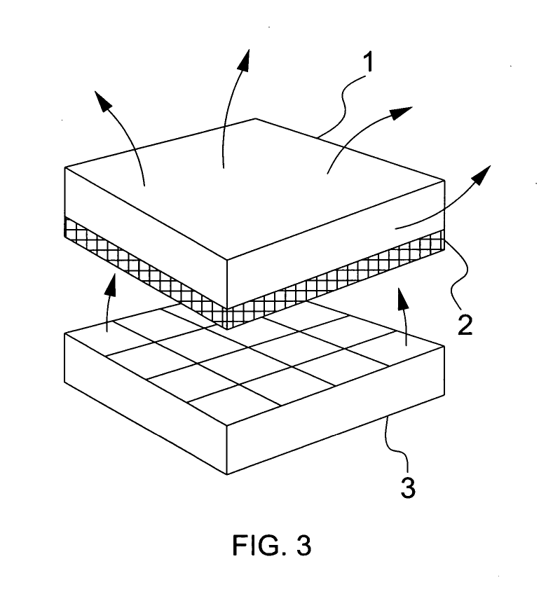

Please further refer to FIG. 3, which is a cross-sectional view of a third preferred embodiment according to the present invention. As shown in the figure, when the present invention is applied to a large area according to an actual requirement from a user, the light-emitting device 3a can be a plurality of nanoparticles or can be nanoparticles arranged into a matrix layout with lows and columns interlaced. By doing so, the present invention can be applied to a large area to obtain a white light source from a large area.

To sum up, the present invention is a white-light luminescent silicon-nitride component with silicon quantum dots and a fabricating method thereof, where the light-emitting device of the present invention comprises high luminescent efficiency, large-area luminescence, cheap raw material and low producing cost.

The preferred embodiment(s) here in disclosed is/are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A white-light luminescent silicon-nitride component with silicon quantum dots, comprising:
(a) a substrate;
(b) a silicon nitride film layer with silicon quantum dots, said silicon nitride film layer depositing on a surface of said substrate; and
(c) a light-emitting device deposing on a surface of said silicon nitride film layer, said light-emitting device emitting a light source to said silicon nitride film layer to pump said silicon nitride film layer to generate a white light.

2. The component according to claim 1, wherein said substrate is made of a material selected from a group consisting of a glass and a quartz in a shape selected from a group consisting of a flat shape and a cap shape.

3. The component according to claim 1, wherein said substrate comprises a thickness not thicker than 1 mm.

4. The component according to claim 1, wherein said silicon nitride film layer is obtained by a deposition of a precursor selected from a group consisting of dichlorosilane (Si₂H₂Cl₂) together with nitrous oxide (N₂O), and silane (SiH₄) together with ammonia (NH₃).

5. The component according to claim 4, wherein said deposition is processed in a situation selected from a group consisting of using an apparatus for AP-CVD (atmospheric pressure chemical vapor deposition) under a grown temperature between 800° C. (centigrade) and 1,000° C., and using an apparatus for PE-CVD (plasma-enhanced chemical vapor deposition) under a grown temperature between 300° C. and 500° C.

6. The component according to claim 1, wherein said silicon nitride film layer is made of a film selected from a group consisting of a white-light film, a fluorescence film and a ceramic insulator film.

7. The component according to claim 1, wherein said silicon nitride film layer comprises a light spectrum of wavelength between 400 nm (nanometer) and 700 nm.

8. The component according to claim 1, wherein said silicon nitride film layer comprises a thickness between 1 μm (micrometer) and 10 μm.

9. The component according to claim 1, wherein said light-emitting device is made of UV-LED (Ultraviolet Light-Emitting Diode) in a form selected from a group consisting of a single nanoparticle, a plurality of nanoparticles, and nanoparticles arranged into a matrix layout.

10. The component according to claim 1, wherein said white light generated by said silicon nitride film layer comprises a wavelength shorter than 400 nm.

11. A fabricating method for a white-light luminescent silicon-nitride component with silicon quantum dots, comprising steps of:
(a) Selecting a substrate, applying a precursor of dichlorosilane together with nitrous oxide to be deposed on said substrate, obtaining a silicon nitride compound having a non-stoichiometric ratio by a deposition of said precursor through using an apparatus for AP-CVD under a grown temperature between 800° C. and 1000° C., and obtaining a silicon nitride film layer with evenly distributed silicon quantum dots through a thermo-treatment, wherein said silicon nitride film layer comprises a lightspectrum of wavelength between 400 nm and 700 nm; and
(b) correspondingly deposing a light-emitting device on a surface of said silicon nitride film layer, wherein said light-emitting device emits a light source having a wavelength shorter then 400 nm to said silicon nitride film layer to pump said silicon nitride film layer to generate a white light.

12. The fabricating method according to claim 11, wherein said substrate is made of a material selected from a group consisting of a glass and a quartz in a shape selected from a group consisting of a flat shape and a cap shape.

13. The fabricating method according to claim 11, wherein said substrate comprises a thickness not thicker than 1 mm.

14. The fabricating method according to claim 11, wherein said precursor is silane (SiH₄) together with ammonia (NH₃).

15. The fabricating method according to claim 11, wherein said deposition of said precursor is processed through using an apparatus for PE-CVD under a grown temperature between 300° C. and 500° C.

16. The fabricating method according to claim 11, wherein said silicon nitride film layer comprises a thickness between 1 μm and 10 μm.

17. The fabricating method according to claim 11, wherein said silicon quantum dot comprises a diameter smaller then 5 nm.

18. The fabricating method according to claim 11, wherein said silicon nitride film layer is made of a material selected from a group consisting of a white-light film, a fluorescence film and a ceramic insulator film.

19. The fabricating method according to claim 11, wherein said light-emitting device is made of UV-LED in a form selected from a group consisting of a single nanoparticle, a plurality of nanoparticles, and nanoparticles arranged into a matrix layout.
